(19) United States
(12) Patent Application Publication
(10) Pub. No.: US 2024/0334746 A1
(43) Pub. Date: Oct. 3, 2024

(54) DISPLAY DEVICE AND METHOD OF FABRICATING THE SAME

(71) Applicant: Samsung Display Co., LTD., Yongin-si (KR)

(72) Inventors: Hyun Eok SHIN, Yongin-si (KR); Dong Min LEE, Yongin-si (KR); Ju Hyun LEE, Yongin-si (KR); Yung Bin CHUNG, Yongin-si (KR)

(73) Assignee: Samsung Display Co., LTD., Yongin-si (KR)

(21) Appl. No.: 18/515,550

(22) Filed: Nov. 21, 2023

(30) Foreign Application Priority Data
Mar. 29, 2023 (KR) 10-2023-0041433

(51) Int. Cl. H10K 59/122; H10K 59/12

(52) U.S. Cl. CPC H10K 59/122; H10K 59/1201

(57) ABSTRACT

A display device includes a transistor layer disposed on a substrate and including at least one transistor, an insulating layer disposed on the transistor layer, a first pixel electrode disposed on the insulating layer, a first pixel defining layer covering a side surface of the first pixel electrode and a side surface of the insulating layer and defining a first emission area, a first light emitting layer disposed in the first emission area on the first pixel electrode, a first common electrode disposed on the first light emitting layer, and a bank disposed on the insulating layer and surrounding the first pixel electrode. The first pixel electrode and the bank are disposed on a same layer and include a same material.

### CROSS REFERENCE TO RELATED APPLICATION(S)

This application claims priority to and benefits Korean Patent Application No. 10-2023-0041433 under 35 U.S.C. § 119, filed on Mar. 29, 2023, in the Korean Intellectual Property Office (KIPO), the entire contents of which are incorporated herein by reference.

### BACKGROUND

### 1. Technical Field

The disclosure relates to a display device and a method of fabricating (or manufacturing) the same.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, smart televisions, and the like. The display device may be a flat panel display device such as a liquid crystal display device, a field emission display device, an organic light emitting display device, and the like. Among the flat panel display devices, in the light emitting display device, since each of pixels of a display panel includes a light emitting element that emits light by itself, an image can be displayed without a light emitting device providing light to the display panel.

### SUMMARY

The disclosure provides a display device, capable of improving an emission efficiency of a light emitting element and readily implementing high-resolution ultra-fine process, and a method of manufacturing the same.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an embodiment, a display device may include a transistor layer disposed on a substrate and including at least one transistor, an insulating layer disposed on the transistor layer, a first pixel electrode disposed on the insulating layer, a first pixel defining layer covering a side surface of the first pixel electrode and a side surface of the insulating layer and defining a first emission area, a first light emitting layer disposed in the first emission area on the first pixel electrode, a first common electrode disposed on the first light emitting layer, and a bank disposed on the insulating layer and surrounding the first pixel electrode. The first pixel electrode and the bank may be disposed on a same layer and include a same material.

The bank may include a first bank disposed on the insulating layer, a second bank disposed on the first bank, and a third bank disposed on the second bank.

A side surface of the first bank and a side surface of the second bank may be recessed inward from a side surface of the third bank.

The third bank may include a tip protruding from a side surface of the second bank.

The first common electrode may cover the first pixel defining layer and the insulating layer and may extend to a side surface of the first bank.

The first pixel electrode may include a first layer disposed on the insulating layer and a second layer disposed on the first layer.

The first layer of the first pixel electrode and the first bank may be disposed on a same layer and include a same material. The second layer of the first pixel electrode and the second bank may be disposed on a same layer and include a same material.

The display device may further include a second pixel electrode disposed on the insulating layer, a second pixel defining layer covering a side surface of the insulating layer and a side surface of the second pixel electrode and defining a second emission area, a second light emitting layer disposed in the second emission area on the second pixel electrode, and a second common electrode disposed on the second light emitting layer.

The second pixel electrode may include a first layer, the first layer and the first bank disposed on a same layer and including a same material, and a second layer, the second layer and the second bank disposed on a same layer and including a same material.

The first and second common electrodes may be electrically connected through the first bank.

The display device may further include an electrode pattern disposed on the third bank, the electrode pattern and the first common electrode including a same material.

The display device may further include a first encapsulation layer disposed on the first common electrode and the electrode pattern, and covering side surfaces of the first and second banks.

According to an embodiment, a display device may include a transistor layer disposed on a substrate and including at least one transistor, a first pixel electrode disposed on the transistor layer, a first pixel defining layer covering a side surface of the first pixel electrode and defining a first emission area, a first light emitting layer disposed in the first emission area on the first pixel electrode, a first common electrode disposed on the first light emitting layer, and a bank disposed on the transistor layer and surrounding the first pixel electrode. The first pixel electrode and the bank may be disposed on a same layer and include a same material.

The bank may include a first bank disposed on the transistor layer, a second bank disposed on the first bank, and a third bank disposed on the second bank.

The first pixel electrode may include a first layer, the first layer and the first bank disposed on a same layer and including a same material, and a second layer, the second layer and the second bank disposed on a same layer and including a same material.

According to an embodiment, a method of manufacturing a display device may include forming an insulating layer on a substrate, forming a first layer of a first pixel electrode and a first bank on the insulating layer, forming a second layer of a first pixel electrode on the first layer of the first pixel electrode and forming a second bank on the first bank, forming a temporary pixel electrode on the second layer of the first pixel electrode and forming a third bank on the second bank, forming a halftone photoresist on the temporary pixel electrode and forming a photoresist that is thicker than the halftone photoresist on the third bank, and removing the halftone photoresist and the temporary pixel electrode by an etching process and etching a side surface of the first bank and a side surface of the second bank to form a tip of the third bank.

The method may further include removing the photoresist by a stripping process.

The method may further include forming a first pixel defining layer covering a side surface of the insulating layer, a side surface of the first pixel electrode, and an edge of a top surface of the second layer of the first pixel electrode to define a first emission area.

The method may further include forming a first light emitting layer in the first emission area on the second layer of the first pixel electrode.

The method may further include forming a first common electrode on the first light emitting layer and forming an electrode pattern on the third bank. The forming of the first common electrode and the forming of the electrode pattern may include depositing a metal material to cut and separate the first common electrode and the electrode pattern by the tip of the third bank.

In the display device and the method of manufacturing the same according to embodiments, it is possible to improve emission efficiency and readily implement high-resolution ultra-fine process, since light emitted from a light emitting element is not blocked by a bank by including a light emitting element having a height similar to the height of the bank.

However, the effects of the disclosure are not limited to the aforementioned effects, and various other effects are included in the specification.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a display device according to an embodiment;

FIG. 2 is a schematic cross-sectional view illustrating a display device according to an embodiment;

FIG. 3 is a schematic plan view illustrating a display part of a display device according to an embodiment;

FIG. 4 is a schematic cross-sectional view illustrating a portion of a display device according to an embodiment;

FIG. 5 is a schematic enlarged view of area A1 of FIG. 4;

FIGS. 6 to 12 are schematic cross-sectional views illustrating a manufacturing process of a display device of FIG. 4;

FIG. 13 is a schematic cross-sectional view illustrating a portion of a display device according to another embodiment; and

FIG. 14 is a schematic enlarged view of area A2 of FIG. 13.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods employing one or more of the disclosure disclosed herein. It is apparent, however, that various embodiments may be practiced without these specific details or with one or more equivalent arrangements. In other instances, structures and devices are shown in block diagram form in order to avoid unnecessarily obscuring various embodiments. Further, various embodiments may be different, but do not have to be exclusive nor limit the disclosure. For example, specific shapes, configurations, and characteristics of an embodiment may be used or implemented in other embodiments without departing from the disclosure.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on” or “connected to” another element or layer, it may be directly on, connected to, or coupled to the other element or layer or intervening elements or layers may be present. When, however, an element or layer is referred to as being “directly on” or “directly connected to” another element or layer, there are no intervening elements or layers present. To this end, the term “connected” may refer to physical, electrical, and/or fluid connection, with or without intervening elements.

When a component is described herein to “connect” another component to the other component or to be “connected to” other components, the components may be connected to each other as separate elements, or the components may be integral with each other.

Throughout the specification, when an element is referred to as being “connected” to another element, the element may be “directly connected” to another element, or “electrically connected” to another element with one or more intervening elements interposed therebetween. Also, when an element is referred to as being “in contact” or “contacted” or the like to another element, the element may be in “electrical contact” or in “physical contact” with another element; or in “indirect contact” or in “direct contact” with another element.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, ZZ, or the like. As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or.”

Although the terms “first.” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below.” “under,” “lower,” “above.” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises.” “comprising,” “includes,” “including.” “has,” and/or “having.” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially.” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not necessarily intended to be limiting.

The display surface may be parallel to a surface defined by an X-axis direction and a Y-axis direction. A normal direction of the display surface, i.e., a thickness direction of the display device 10, may indicate a Z-axis direction. In this specification, an expression of “when viewed from the top or in a plan view” may represent a case when viewed in the Z-axis direction. Hereinafter, a front surface (or a top surface) and a rear surface (or a bottom surface) of each of layers or units may be distinguished by the Z-axis direction. However, directions indicated by the X-axis to Z-axis directions may be a relative concept, and converted with respect to each other, e.g., converted into opposite directions.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, detailed embodiments of the disclosure are described with reference to the accompanying drawings.

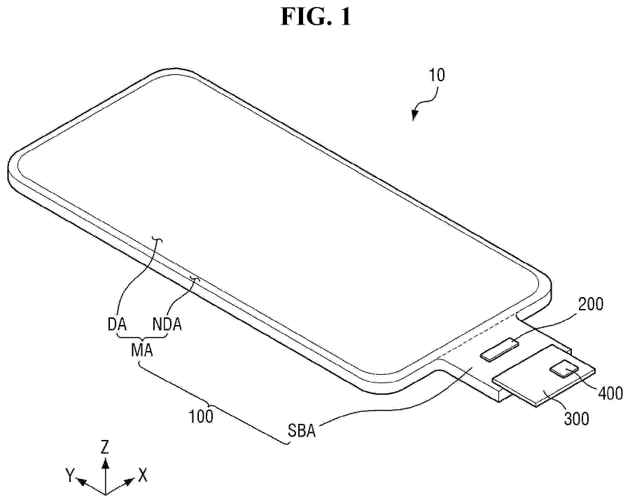

FIG. 1 is a schematic perspective view illustrating a display device 10 according to an embodiment.

Referring to FIG. 1, a display device 10 may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC), or the like. For example, the display device 10 may be applied as a display part of a television, a laptop, a monitor, a billboard, Internet-of-Things (IoT) device, or the like. In another embodiment, the display device 10 may be applied to wearable devices such as a smart watch, a watch phone, a glasses type display, a head mounted display (HMD), or the like.

The display device 10 may have a quadrilateral shape in a plan view. For example, the display device 10 may have a quadrilateral shape, in a plan view, having short sides in an X-axis direction and long sides in a Y-axis direction. The Y-axis direction may intersect the x-axis direction. A corner where the short side in the X-axis direction and the long side in the Y-axis direction meet may be rounded with a curvature (e.g., a predetermined or selectable curvature) or may be right-angled. However, the shape of the display device 10 is not limited thereto, and the shape of display device 10 may be formed in a shape similar to another polygonal shape, a circular shape, elliptical shape, or the like in a plan view.

The display device 10 may include a display panel 100, a display driver 200, a circuit board 300, and a touch driver 400.

The display panel 100 may include a main region MA and a sub-region SBA.

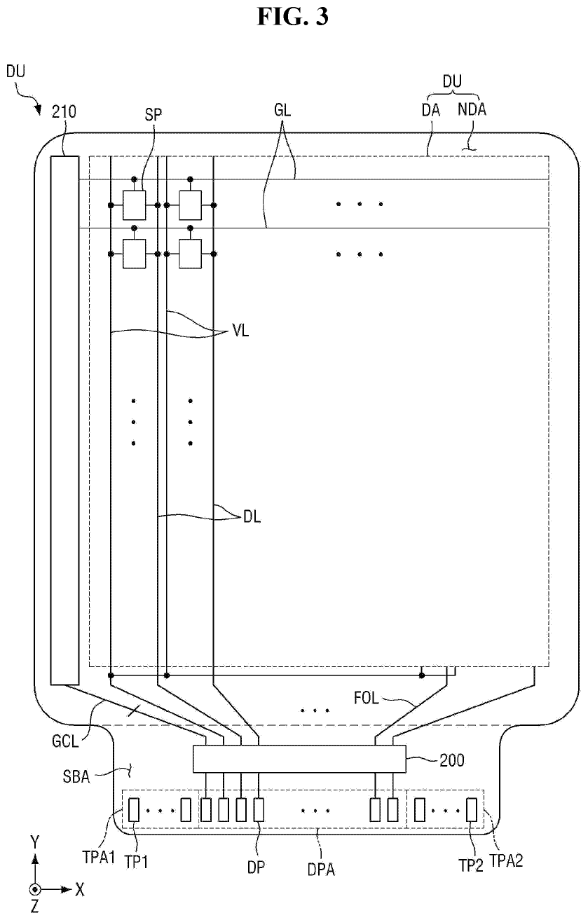

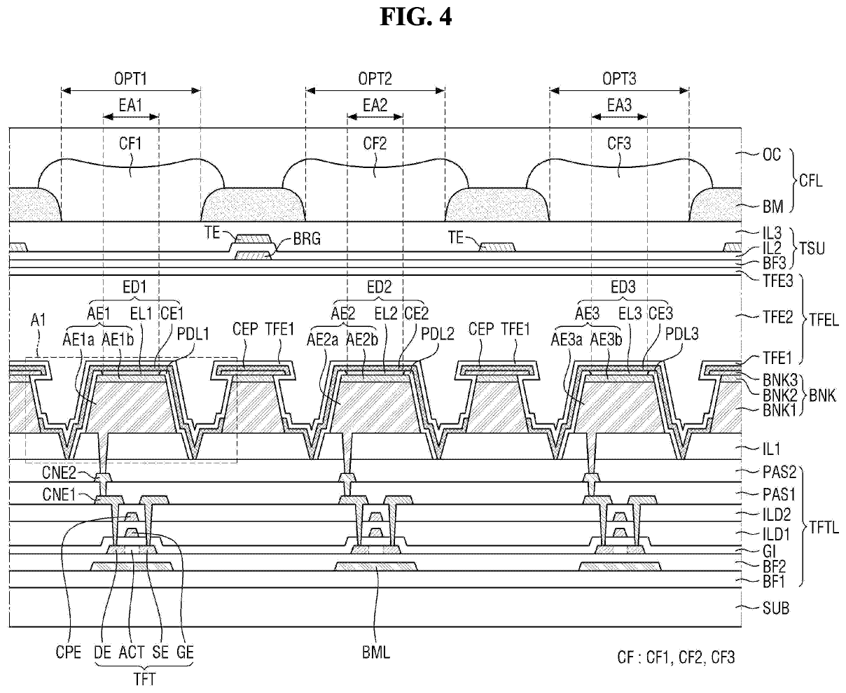

The main region MA may include a display area DA including pixels (see, e.g., SP of FIG. 3) displaying an image and a non-display area NDA disposed adjacent to the display area DA. For example, the non-display area NDA may surround at least a portion of the display area DA. The display area DA may emit light from multiple emission areas (see, e.g., EA1 to EA3 of FIG. 4) or multiple opening areas. For example, the display panel 100 may include a pixel circuit (not illustrated) including switching elements, a pixel defining layer (not illustrated) defining an emission area or an opening area, a self-light emitting element (not illustrated), the like, or a combination thereof.

For example, the self-light emitting element may include at least one of an organic light emitting diode including an organic light emitting layer, a quantum dot light emitting diode including a quantum dot light emitting layer, an inorganic light emitting diode including an inorganic semiconductor, and a micro light emitting diode (micro LED), but the disclosure is not limited thereto.

The non-display area NDA may be an area disposed adjacent to (or surrounding) the display area DA. The non-display area NDA may be an edge area of the main region MA of the display panel 100. The non-display area NDA may include a gate driver (see, e.g., 210 of FIG. 3) that supplies gate signals to gate lines (see, e.g., GL of FIG. 3), and fan-out lines (see, e.g., FOL of FIG. 3) that connect a display driver 200 to the display area DA.

The sub-region SBA may extend from a side of the main region MA in the Y-axis direction. The sub-region SBA may include a flexible material which can be bent, folded, or rolled. For example, in case that the sub-region SBA is bent, the sub-region SBA may overlap the main region MA in a thickness direction (Z-axis direction). The Z-axis direction may intersect the X-axis and Y-axis directions. The sub-region SBA may include the display driver 200 and a pad part (not illustrated) connected to the circuit board 300. In another embodiment, the sub-region SBA may be omitted, and the display driver 200 and the pad part may be arranged in the non-display area NDA.

The display driver 200 may output signals and voltages for driving the display panel 100. The display driver 200 may supply data voltages to data lines (see, e.g., DL of FIG. 3). The display driver 200 may supply a power voltage to a power line (not illustrated) and supply a gate control signal to the gate driver. The display driver 200 may be formed as an integrated circuit (IC) and mounted on the display panel 100 by a chip on glass (COG) method, a chip on plastic (COP) method, an ultrasonic bonding method, or the like. For example, the display driver 200 may be disposed in the sub-region SBA, and overlap the main region MA in the thickness direction (Z-axis direction) by bending of the sub-region SBA. In another embodiment, the display driver 200 may be mounted on the circuit board 300.

The circuit board 300 may be attached to the pad part of the display panel 100 by using an anisotropic conductive film (ACF) or the like. Lead lines (not illustrated) of the circuit board 300 may be electrically connected to a pad part of the display panel 100. The circuit board 300 may be a flexible printed circuit board, a printed circuit board, a flexible film such as a chip on film, or the like.

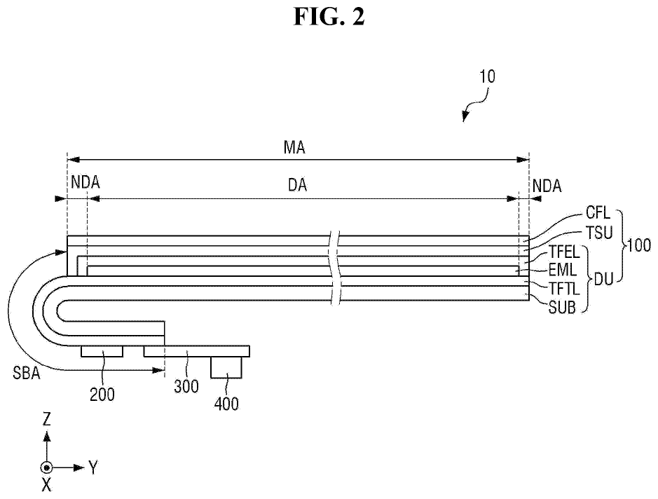

A touch driver 400 may be mounted on the circuit board 300. The touch driver 400 may be electrically connected to a touch sensing part (see, e.g., TSU of FIG. 2) of the display panel 100. The touch driver 400 may supply a touch driving signal to multiple touch electrodes (see, e.g., TE of FIG. 4) of the touch sensing part and sense an amount of change in capacitance between the touch electrodes. For example, the touch driving signal may be a pulse signal having a frequency (e.g., a predetermined or selectable frequency). The touch driver 400 may calculate whether an input is made and input coordinates based on an amount of change in capacitance between the touch electrodes. The touch driver 400 may be formed of an integrated circuit (IC).

FIG. 2 is a schematic cross-sectional view illustrating a display device 10 according to an embodiment.

Referring to FIG. 2, the display panel 100 may include a display part DU, a touch sensing part TSU, and a color filter layer CFL. The display part DU may include a substrate SUB, a transistor layer TFTL, a light emitting element layer EML, and an encapsulation layer TFEL.

The substrate SUB may be a base substrate or a base member. The substrate SUB may be a flexible substrate which can be bent, folded, or rolled. For example, the substrate SUB may include a polymer resin including polyimide (PI) or the like, but the disclosure is not limited thereto. In another embodiment, the substrate SUB may include a glass material, a metal material, the like, or a combination thereof.

The transistor layer TFTL may be disposed on the substrate SUB. The transistor layer TFTL may include multiple transistors (see, e.g., TFT of FIG. 4) constituting a pixel circuit of pixels (see, e.g., SP of FIG. 3). The transistor layer TFTL may further include gate lines (see, e.g., GL of FIG. 3), data lines (see, e.g., DL of FIG. 3), power lines (see, e.g., VL of FIG. 3), gate control lines (see, e.g., GCL of FIG. 3), fan-out lines (see, e.g., FOL of FIG. 3) that connect the display driver 200 to the data lines, and lead lines (not illustrated) that connect the display driver 200 to the pad part. Each of the transistors may include a semiconductor region (see, e.g., ACT of FIG. 4), a source electrode (see, e.g., SE of FIG. 4), a drain electrode (see, e.g., DE of FIG. 4), and a gate electrode (see, e.g., GE of FIG. 4). For example, in case that the gate driver (see, e.g., 210 of FIG. 3) is formed on a side of the non-display area NDA of the display panel 100, the gate driver may include transistors.

The transistor layer TFTL may be disposed in the display area DA, the non-display area NDA, and the sub-region SBA. The transistors, the gate lines, the data lines, and the power lines of each of the pixels of the transistor layer TFTL may be disposed in the display area DA. The gate control lines and the fan-out lines of the transistor layer TFTL may be disposed in the non-display area NDA. The lead lines of the transistor layer TFTL may be disposed in the sub-region SBA.

The light emitting element layer EML may be disposed on the transistor layer TFTL. The light emitting element layer EML may include multiple light emitting elements in which a pixel electrode (see, e.g., AE1 to AE3 of FIG. 4), a light emitting layer (see, e.g., EL1 to EL3 of FIG. 4), and a common electrode (see, e.g., CE1 to CE3 of FIG. 4) are sequentially stacked to emit light, and a pixel defining layer (see, e.g., PDL1 to PDL3 of FIG. 4) defining pixels. Multiple light emitting elements (see, e.g., ED1 to ED3 of FIG. 4) of the light emitting element layer EML may be disposed in the display area DA.

For example, the light emitting layer may be an organic light emitting layer including an organic material. The light emitting layer may include a hole transporting layer (not illustrated), an organic light emitting layer (not illustrated), and an electron transporting layer (not illustrated). In case that the pixel electrode receives a voltage (e.g., a predetermined or selectable voltage) from the transistor of the transistor layer TFTL and the common electrode receives a cathode voltage, holes may be transferred to the organic light emitting layer through the hole transporting layer and electrons may be transferred to the electron transporting layer, and be combined with each other to emit light in the organic light emitting layer. For example, the pixel electrode may be an anode electrode, and the common electrode may be a cathode electrode, but the disclosure is not limited thereto.

In another embodiment, the light emitting elements may include a quantum dot light emitting diode including a quantum dot light emitting layer, an inorganic light emitting diode including an inorganic semiconductor, a micro light emitting diode, the like, or a combination thereof.

The encapsulation layer TFEL may cover (or be disposed on) a top surface and a side surface of the light emitting element layer EML, and protect the light emitting element layer EML. The encapsulation layer TFEL may include at least one inorganic layer and at least one organic layer for encapsulating the light emitting element layer EML.

The touch sensing part TSU may be disposed on the encapsulation layer TFEL. The touch sensing part TSU may include multiple touch electrodes (see, e.g., TE of FIG. 4) for sensing a user's touch in a capacitive manner, and touch lines (not illustrated) connecting the touch electrodes to the touch driver 400. For example, the touch sensing part TSU may sense the user's touch by using a mutual capacitance method, a self-capacitance method, the like, or a combination thereof.

In another embodiment, the touch sensing part TSU may be disposed on a separate substrate (not illustrated) disposed on the display part DU. For example, the separate substrate supporting the touch sensing part TSU may be a base member that encapsulates the display part DU.

The touch electrodes of the touch sensing part TSU may be disposed in a touch sensor area (not illustrated) overlapping the display area DA in the thickness direction. The touch lines of the touch sensing part TSU may be disposed in a touch peripheral area (not illustrated) that overlaps the non-display area NDA in the thickness direction.

The color filter layer CFL may be disposed on the touch sensing part TSU. The color filter layer CFL may include multiple color filters (see, e.g., CF of FIG. 4) respectively corresponding to the emission areas (see, e.g., EA1 to EA3 of FIG. 4). Each of the color filters may selectively transmit light of a wavelength (e.g., a specific wavelength) and block or absorb light of other wavelengths. The color filter layer CFL may absorb a portion of light coming from an outside of the display device 10 and reduce reflected light due to external light. Accordingly, the color filter layer CFL may prevent color distortion caused by reflection of the external light.

Since the color filter layer CFL is disposed (e.g., directly disposed) on the touch sensing part TSU, the display device 10 may not require a separate substrate for the color filter layer CFL. Therefore, a thickness of the display device 10 may be relatively reduced.

The sub-region SBA of the display panel 100 may extend from a side of the main region MA. The sub-region SBA may include a flexible material which can be bent, folded, or rolled. For example, in case that the sub-region SBA is bent, the sub-region SBA may overlap the main region MA in a thickness direction of the display device 10 (Z-axis direction). The sub-region SBA may include the display driver 200 and the pad part electrically connected to the circuit board 300.

FIG. 3 is a schematic plan view illustrating a display part DU of a display device 10 according to an embodiment.

Referring to FIG. 3, the display part DU may include the display area DA and the non-display area NDA.

The display area DA, which is an area for displaying an image, may be a central area of the display panel 100. The display area DA may include multiple pixels SP, multiple gate lines GL, multiple data lines DL, and multiple power lines VL. Each of the pixels SP may be the smallest unit that outputs light.

The gate lines GL may supply the gate signals received from a gate driver 210 to the pixels SP. The gate lines GL may extend in the X-axis direction and be spaced apart from each other in the Y-axis direction that intersects the X-axis direction.

The data lines DL may supply the data voltages received from the display driver 200 to the pixels SP. The data lines DL may extend in the Y-axis direction and be spaced apart from each other in the X-axis direction.

The power lines VL may supply the power voltage received from the display driver 200 to the pixels SP. The power voltage may be at least one of a driving voltage, an initialization voltage, a reference voltage, and a low potential voltage. The power lines VL may extend in the Y-axis direction and be spaced apart from each other in the X-axis direction.

The non-display area NDA may surround (or be disposed adjacent to) the display area DA. The non-display area NDA may include the gate driver 210, fan-out lines FOL, and gate control lines GCL. The gate driver 210 may generate multiple gate signals based on the gate control signal, and sequentially supply the gate signals to the gate lines GL according to a set order.

The fan-out lines FOL may extend from the display driver 200 to the display area DA. The fan-out lines FOL may supply the data voltage received from the display driver 200 to the data lines DL.

The gate control line GCL may extend from the display driver 200 to the gate driver 210. The gate control line GCL may supply the gate control signal received from the display driver 200 to the gate driver 210.

The sub-region SBA may include the display driver 200, a display pad area DPA, and first and second touch pad areas TPA1 and TPA2.

The display driver 200 may output signals and voltages for driving the display panel 100 to the fan-out lines FOL. The display driver 200 may supply a data voltage to the data line DL through the fan-out lines FOL. The data voltage may be supplied to the pixels SP and determine a luminance of the pixels SP. The display driver 200 may supply the gate control signal to the gate driver 210 through the gate control line GCL.

The display pad area DPA, the first touch pad area TPA1, and the second touch pad area TPA2 may be disposed at an edge of the sub-region SBA. The display pad area DPA, the first touch pad area TPA1, and the second touch pad area TPA2 may be electrically connected to the circuit board 300 by using a low-resistance high-reliability material such as an anisotropic conductive film, self assembly anisotropic conductive paste (SAP), the like, or a combination thereof.

The display pad area DPA may include multiple display pad parts DP. The display pad DP may be disposed in the display pad area DPA. The display pad parts DP may be electrically connected to a graphic system through the circuit board 300. The display pad parts DP may be connected to the circuit board 300, receive digital video data, and supply the digital video data to the display driver 200.

The first touch pad area TPA1 may be disposed in an area on a side of the display pad area DPA, and include multiple first touch pad parts TP1. The first pad parts TP1 may be disposed in the first touch pad area TPA1. The first touch pad parts TP1 may be electrically connected to the touch driver 400 disposed on the circuit board 300. The first touch pad parts TP1 may supply a touch driving signal to the driving electrodes through multiple driving lines.

The second touch pad area TPA2 may be disposed in another area on another side of the display pad area DPA, and include multiple second touch pad parts TP2. The second pad parts TP2 may be disposed in the second touch pad area TPA2. The second touch pad parts TP2 may be electrically connected to the touch driver 400 disposed on the circuit board 300. The touch driver 400 may receive a touch sensing signal through multiple sensing lines connected to the second touch pad parts TP2, and sense a change in mutual capacitance between a driving electrode (not illustrated) and a sensing electrode (not illustrated).

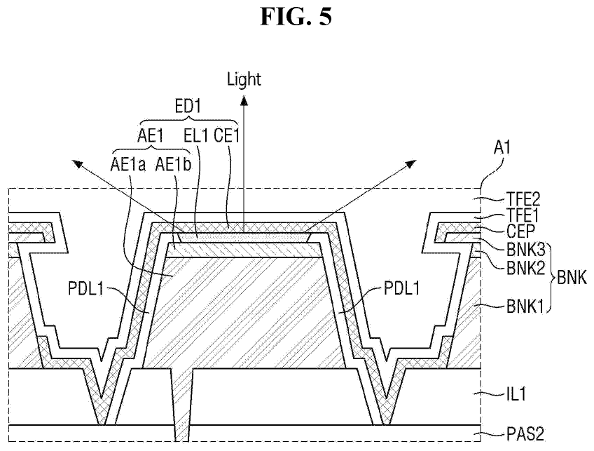

FIG. 4 is a schematic cross-sectional view illustrating a portion of a display device 10 according to an embodiment, and FIG. 5 is a schematic enlarged view of area A1 of FIG. 4.

Referring to FIGS. 2, 4, and 5, the display panel 100 may include a display part DU, a touch sensing part TSU, and a color filter layer CFL. The display part DU may include the substrate SUB, the transistor layer TFTL, the light emitting element layer EML, and the encapsulation layer TFEL.

The substrate SUB may be a base substrate or a base member. The substrate SUB may be a flexible substrate which can be bent, folded, or rolled. For example, the substrate SUB may include a polymer resin including polyimide (PI) or the like, but the disclosure is not limited thereto. In another embodiment, the SUB may include a glass material, a metal material, the like, or a combination thereof.

The transistor layer TFTL may include a first buffer layer BF1, a light blocking layer BML, a second buffer layer BF2, a transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The first buffer layer BF1 may be disposed on the substrate SUB. The first buffer layer BF1 may include an inorganic layer that prevents penetration of air or moisture. For example, the first buffer layer BF1 may include multiple inorganic layers alternately stacked with each other.

The light blocking layer BML may be disposed on the first buffer layer BF1. For example, the light blocking layer BML may be formed as a single layer or multiple layers including at least one of molybdenum (Mo), aluminum (Al), chromium (Cr), gold (Au), titanium (Ti), nickel (Ni), neodymium (Nd), copper (Cu), and an alloy thereof. In another embodiment, the light blocking layer BML may be an organic layer including a black pigment or the like.

The second buffer layer BF2 may be disposed on the first buffer layer BF1 and the light blocking layer BML. The second buffer layer BF2 may include an inorganic layer that prevents penetration of air or moisture. For example, the second buffer layer BF2 may include multiple inorganic layers alternately stacked with each other.

The transistor TFT may be disposed on the second buffer layer BF2, and constitute a pixel circuit of each of multiple pixels SP. For example, the transistor TFT may be a switching transistor or a driving transistor of the pixel circuit. The transistor TFT may include a semiconductor region ACT, a source electrode SE, a drain electrode DE, and a gate electrode GE.

The semiconductor region ACT, the source electrode SE, and the drain electrode DE may be disposed on the second buffer layer BF2. The semiconductor region ACT, the source electrode SE, and the drain electrode DE may overlap the light blocking layer BML in a thickness direction (Z-axis direction). The semiconductor region ACT may overlap the gate electrode GE in the thickness direction. The source electrode SE and the drain electrode DE may be provided by making a material of the semiconductor region ACT conductive.

The gate electrode GE may be disposed on the gate insulating layer GI. The gate electrode GE may overlap the semiconductor region ACT with the gate insulating layer GI interposed between the semiconductor region ACT and the gate electrode GE in the thickness direction.

The gate insulating layer GI may be disposed on the semiconductor region ACT, the source electrode SE, and the drain electrode DE. For example, the gate insulating layer GI may cover the semiconductor region ACT, the source electrode SE, the drain electrode DE, and the second buffer layer BF2, and insulate the semiconductor region ACT from the gate electrode GE.

The first interlayer insulating layer ILD1 may be disposed on the gate electrode GE and the gate insulating layer GI. The first interlayer insulating layer ILD1 may insulate the gate electrode GE from the capacitor electrode CPE.

The capacitor electrode CPE may be disposed on the first interlayer insulating layer ILD1. The capacitor electrode CPE may overlap the gate electrode GE in the thickness direction. The capacitor electrode CPE and the gate electrode GE may form a capacitance.

The second interlayer insulating layer ILD2 may be disposed on the capacitor electrode CPE and the first interlayer insulating layer ILD1. The second interlayer insulating layer ILD2 may insulate the capacitor electrode CPE from the first connection electrode CNE1.

The first connection electrode CNE1 may be disposed on the second interlayer insulating layer ILD2. The first connection electrode CNE1 may electrically connect the drain electrode DE of the transistor TFT to the second connection electrode CNE2. The first connection electrode CNE1 may be inserted into a contact hole provided in the second interlayer insulating layer ILD2, the first interlayer insulating layer ILD1, and the gate insulating layer GI and contact the drain electrode DE of the transistor TFT.

The first passivation layer PAS1 may cover the first connection electrode CNE1 and the second interlayer insulating layer ILD2. The first passivation layer PAS1 may protect the transistor TFT. The first passivation layer PAS1 may insulate the first connection electrode CNE1 from the second connection electrode CNE2.

The second connection electrode CNE2 may be disposed on the first passivation layer PAS1. The second connection electrode CNE2 may electrically connect the first connection electrode CNE1 to a first pixel electrode AE1 of a first light emitting element ED1. The second connection electrode CNE2 may be inserted into a contact hole provided in the first passivation layer PAS1 and contact the first connection electrode CNE1.

The second passivation layer PAS2 may be disposed on the second connection electrode CNE2 and the first passivation layer PAS1. The second passivation layer PAS2 may insulate the second connection electrode CNE2 from the first pixel electrode AE1.

The light emitting element layer EML may be disposed on the transistor layer TFTL. The light emitting element layer EML may include a first insulating layer IL1, first to third light emitting elements ED1, ED2, and ED3, first to third pixel defining layers PDL1, PDL2, and PDL3, banks BNK, and electrode patterns CEP.

The display device 10 may include multiple pixels SP arranged in multiple rows and columns in the display area DA. Each of the pixels SP may include first to third emission areas EA1, EA2, and EA3 defined by first to third pixel defining layers PDL1, PDL2, and PDL3, respectively, and emit light having a peak wavelength (e.g., a predetermined or selectable peak wavelength) through the first to third emission areas EA1, EA2, and EA3. Each of the first to third emission areas EA1, EA2, and EA3 may be an area in which light generated from a light emitting element of the display device 10 is emitted to an outside of the display device 10.

The first to third emission areas EA1, EA2, and EA3 may emit light having a peak wavelength (e.g., a predetermined or selectable peak wavelength) to the outside of the display device 10. The first emission area EA1 may emit light of a first color, the second emission area EA2 may emit light of a second color, and the third emission area EA3 may emit light of a third color. For example, the first color light may be red light having a peak wavelength in a range of about 610 nm to about 650 nm, the second color light may be green light having a peak wavelength in a range of about 510 nm to about 550 nm, and the third color light may be blue light having a peak wavelength in a range of about 440 nm to about 480 nm, but the disclosure is not limited thereto.

For example, a size of the third emission area EA3 may be greater than a size of the first emission area EA1, and the size of the first emission area EA1 may be greater than a size of the second emission area EA2 in a plan view. However, the disclosure is not limited thereto. In another embodiment, the size of the first emission area EA1, the size of the second emission area EA2 and the size of the third emission area EA3 may be substantially all equal.

The first insulating layer IL1 may be disposed on the transistor layer TFTL. The first insulating layer IL1 may support the first to third pixel electrodes AE1, AE2, and AE3 and the banks BNK. A height of the first insulating layer IL1 may determine heights of the first to third light emitting elements ED1, ED2, and ED3 and the bank BNK. The first insulating layer IL1 supporting the first pixel electrode AE1, the first insulating layer IL1 supporting the second pixel electrode AE2, the first insulating layer IL1 supporting the third pixel electrode AE3, and the first insulating layer IL1 supporting the bank BNK may be spaced apart from each other in the X-axis direction and/or the Y-axis direction. The first insulating layer IL1 may include an inorganic insulating material. The first insulating layer IL1 may include at least one of a silicon nitride, a silicon oxynitride, a silicon oxide, a titanium oxide, an aluminum oxide, and an amorphous silicon, but the disclosure is not limited thereto.

The first light emitting element ED1 may be disposed in the first emission area EA1 on the first insulating layer IL1. The first light emitting element ED1 may include the first pixel electrode AE1, a first light emitting layer EL1, and a first common electrode CE1.

The first pixel electrode AE1 may be disposed on the first insulating layer IL1. The first pixel electrode AE1 may be inserted into a contact hole provided in the first insulating layer IL1 and the second passivation layer PAS2 and contact the second connection electrode CNE2. The first pixel electrode AE1 may be electrically connected to the drain electrode DE of the transistor TFT through the first and second connection electrodes CNE1 and CNE2.

The first pixel electrode AE1 may include a first layer AE1a and a second layer AE1b. The first layer AE1a of the first pixel electrode AE1 may be disposed on the first insulating layer IL1, and the second layer AE1b of the first pixel electrode AE1 may be disposed on the first layer AE1a. The first layer AE1a of the first pixel electrode AE1 and a first bank BNK1 may be formed in a same process and include a same metal material. The second layer AE1b of the first pixel electrode AE1 and a second bank BNK2 may be formed in a same process and include a same metal material. A thickness of the first layer AE1a of the first pixel electrode AE1 may be greater than a thickness of the second layer AE1b in the thickness direction.

The first layer AE1a and the second layer AE1b of the first pixel electrode AE1 may include different metal materials. The first layer AE1a of the first pixel electrode AE1 may include a material having high electrical conductivity and high reflectivity. The second layer AE1b of the first pixel electrode AE1 may be an anode electrode for injecting holes. For example, the first layer AE1a of the first pixel electrode AE1 may include aluminum (Al) or the like, and the second layer AE1b of the first pixel electrode AE1 may include titanium nitride (TiN) or the like, but the disclosure is not limited thereto.

The first pixel defining layer PDL1 may define the first emission area EA1. The first pixel defining layer PDL1 may cover (or be disposed on) a side surface of the first insulating layer IL1 disposed in the first emission area EA1, a side surface of the first pixel electrode AE1, and an edge of a top surface of the second layer AE1b of the first pixel electrode AE1. The first pixel defining layer PDL1 may expose a portion of the top surface of the second layer AE1b of the first pixel electrode AE1. The first pixel defining layer PDL1 may insulate the first pixel electrode AE1 from the first common electrode CE1. The first pixel defining layer PDL1 may include an inorganic insulating material. The first pixel defining layer PDL1 may include at least one of a silicon nitride, a silicon oxynitride, a silicon oxide, a titanium oxide, an aluminum oxide, and an amorphous silicon, but the disclosure is not limited thereto.

The first light emitting layer EL1 may be an organic light emitting layer including an organic material. The first light emitting layer EL1 may be disposed (e.g., directly disposed) on the second layer AE1b of the first pixel electrode AE1 in the first emission area EA1. The first light emitting layer EL1 may fill a space surrounded by the first pixel defining layer PDL1.

The first common electrode CE1 may be disposed on the first light emitting layer EL1. The first common electrode CE1 may cover (or be disposed on) the first pixel defining layer PDL1 and the first insulating layer IL1 and extend to a side surface of the first bank BNK1. The first common electrode CE1 may be electrically connected to the second and third common electrodes CE2 and CE3 through the first bank BNK1 by contacting the side surface of the first bank BNK1. For example, the first common electrode CE1 may receive a common voltage or a low potential voltage. The first common electrode CE1 may include a transparent conductive material and transmit light generated in the first light emitting layer EL1.

The first pixel electrode AE1 may receive a voltage corresponding to the data voltage from the transistor TFT and the first common electrode CE1 may receive a common voltage or a cathode voltage. In case that a potential difference is formed between the first pixel electrode AE1 and the first common electrode CE1, holes may move to the first light emitting layer EL1 through the hole transporting layer, and electrons may move to the first light emitting layer EL1 through the electron transporting layer, and the first light emitting layer EL1 may emit light.

The second light emitting element ED2 may be disposed in the second emission area EA2 on the first insulating layer IL1. The second light emitting element ED2 may include the second pixel electrode AE2, a second light emitting layer EL2, and a second common electrode CE2.

The second pixel electrode AE2 may be disposed on the first insulating layer IL1. The second pixel electrode AE2 may be inserted into a contact hole provided in the first insulating layer IL1 and the second passivation layer PAS2 and contact the second connection electrode CNE2. The second pixel electrode AE2 may be electrically connected to the drain electrode DE of the transistor TFT through the first and second connection electrodes CNE1 and CNE2.

The second pixel electrode AE2 may include a first layer AE2a and a second layer AE2b. The first layer AE2a of the second pixel electrode AE2 may be disposed on the first insulating layer IL1, and the second layer AE2b of the second pixel electrode AE2 may be disposed on the first layer AE2a. The first layer AE2a of the second pixel electrode AE2 and the first bank BNK1 may be formed in a same process and include a same metal material. The second layer AE2b of the second pixel electrode AE2 and the second bank BNK2 may be formed in a same process and include a same metal material. A thickness of the first layer AE2a of the second pixel electrode AE2 may be greater than a thickness of the second layer AE2b in the thickness direction.

The first layer AE2a and the second layer AE2b of the second pixel electrode AE2 may include different metal materials from each other. The first layer AE2a of the second pixel electrode AE2 may include a material having high electrical conductivity and high reflectivity. The second layer AE2b of the second pixel electrode AE2 may be an anode electrode for injecting holes. For example, the first layer AE2a of the second pixel electrode AE2 may include aluminum (Al) or the like, and the second layer AE2b of the second pixel electrode AE2 may include titanium nitride (TiN) or the like, but the disclosure is not limited thereto.

The second pixel defining layer PDL2 may define the second emission area EA2. The second pixel defining layer PDL2 may cover (or be disposed on) a side surface of the first insulating layer IL1 disposed in the second emission area EA2, a side surface of the second pixel electrode AE2, and an edge of a top surface of the second layer AE2b of the second pixel electrode AE2. The second pixel defining layer PDL2 may expose a portion of the top surface of the second layer AE2b of the second pixel electrode AE2. The second pixel defining layer PDL2 may insulate the second pixel electrode AE2 from the second common electrode CE2. The second pixel defining layer PDL2 may include an inorganic insulating material. The second pixel defining layer PDL2 may include at least one of a silicon nitride, a silicon oxynitride, a silicon oxide, a titanium oxide, an aluminum oxide, and an amorphous silicon, but the disclosure is not limited thereto.

The second light emitting layer EL2 may be an organic light emitting layer including an organic material. The second light emitting layer EL2 may be disposed (e.g., directly disposed) on the second layer AE2b of the second pixel electrode AE2 in the second emission area EA2. The second light emitting layer EL2 may fill a space surrounded by the second pixel defining layer PDL2.

The second common electrode CE2 may be disposed on the second light emitting layer EL2. The second common electrode CE2 may cover (or be disposed on) the second pixel defining layer PDL2 and the first insulating layer IL1 and extend to a side surface of the first bank BNK1. The second common electrode CE2 may be electrically connected to the first and third common electrodes CE1 and CE3 through the first bank BNK1 by contacting the side surface of the first bank BNK1. For example, the second common electrode CE2 may receive a common voltage or a low potential voltage. The second common electrode CE2 may include a transparent conductive material and transmit light generated in the second light emitting layer EL2.

The second pixel electrode AE2 may receive a voltage corresponding to the data voltage from the transistor TFT and the second common electrode CE2 may receive a common voltage or a cathode voltage. In case that a potential difference is formed between the second pixel electrode AE2 and the second common electrode CE2, holes may move to the second light emitting layer EL2 through the hole transporting layer, and electrons may move to the second light emitting layer EL2 through the electron transporting layer, and the second light emitting layer EL2 may emit light.

The third light emitting element ED3 may be disposed in the third emission area EA3 on the first insulating layer IL1. The third light emitting element ED3 may include the third pixel electrode AE3, a third light emitting layer EL3, and a third common electrode CE3.

The third pixel electrode AE3 may be disposed on the first insulating layer IL1. The third pixel electrode AE3 may be inserted into a contact hole provided in the first insulating layer IL1 and the second passivation layer PAS2 and contact the second connection electrode CNE2. The third pixel electrode AE3 may be electrically connected to the drain electrode DE of the transistor TFT through the first and second connection electrodes CNE1 and CNE2.

The third pixel electrode AE3 may include a first layer AE3a and a second layer AE3b. The first layer AE3a of the third pixel electrode AE3 may be disposed on the first insulating layer IL1, and the second layer AE3b of the third pixel electrode AE3 may be disposed on the first layer AE3a. The first layer AE3a of the third pixel electrode AE3 and the first bank BNK1 may be formed in a same process and include a same metal material. The second layer AE3b of the third pixel electrode AE3 and the second bank BNK2 may be formed in a same process and include a same metal material. A thickness of the first layer AE3a of the third pixel electrode AE3 may be greater than a thickness of the second layer AE3b in the thickness direction.

The first layer AE3a and the second layer AE3b of the third pixel electrode AE3 may include different metal materials from each other. The first layer AE3a of the third pixel electrode AE3 may include a material having high electrical conductivity and high reflectivity. The second layer AE3b of the third pixel electrode AE3 may be an anode electrode for injecting holes. For example, the first layer AE3a of the third pixel electrode AE3 may include aluminum (Al) or the like, and the second layer AE3b of the third pixel electrode AE3 may include titanium nitride (TiN) or the like, but the disclosure is not limited thereto.

The third pixel defining layer PDL3 may define the third emission area EA3. The third pixel defining layer PDL3 may cover (or be disposed on) a side surface of the first insulating layer ILL disposed in the third emission area EA3, a side surface of the third pixel electrode AE3, and an edge of a top surface of the second layer AE3b of the third pixel electrode AE3. The third pixel defining layer PDL3 may expose a portion of the top surface of the second layer AE3b of the third pixel electrode AE3. The third pixel defining layer PDL3 may insulate the third pixel electrode AE3 from the third common electrode CE3. The third pixel defining layer PDL3 may include an inorganic insulating material. The third pixel defining layer PDL3 may include at least one of a silicon nitride, a silicon oxynitride, a silicon oxide, a titanium oxide, an aluminum oxide, and an amorphous silicon, but the disclosure is not limited thereto.

The third light emitting layer EL3 may be an organic light emitting layer including an organic material. The third light emitting layer EL3 may be disposed (e.g., directly disposed) on the second layer AE3b of the third pixel electrode AE3 in the third emission area EA3. The third light emitting layer EL3 may fill a space surrounded by the third pixel defining layer PDL3. The first to third light emitting layers EL1, EL2, and EL3 may be uniformly deposited in the first to third emission areas EA1, EA2, and EA3, respectively, provided by the first to third pixel defining layers PDL1, PDL2, and PDL3, respectively. The first to third light emitting layers EL1, EL2, and EL3 may be uniformly deposited in an area surrounded by the first to third pixel defining layers PDL1, PDL2, and PLD3, respectively in the first to third emission areas EA1, EA2, and EA3, respectively.

The third common electrode CE3 may be disposed on the third light emitting layer EL3. The third common electrode CE3 may cover (or be disposed on) the third pixel defining layer PDL3 and the first insulating layer IL1 and extend to a side surface of the first bank BNK1. The third common electrode CE3 may be electrically connected to the first and second common electrodes CE1 and CE2 through the first bank BNK1 by contacting the side surface of the first bank BNK1. For example, the third common electrode CE3 may receive a common voltage or a low potential voltage. The third common electrode CE3 may include a transparent conductive material and transmit light generated in the third light emitting layer EL3.

The third pixel electrode AE3 may receive a voltage corresponding to the data voltage from the transistor TFT and the third common electrode CE3 may receive a common voltage or a cathode voltage. In case that a potential difference is formed between the third pixel electrode AE3 and the third common electrode CE3, holes may move to the third light emitting layer EL3 through the hole transporting layer, and electrons may move to the third light emitting layer EL3 through the electron transporting layer, and the third light emitting layer EL3 may emit light.

The bank BNK may be disposed on the first insulating layer IL1 and surround the first to third light emitting elements ED1, ED2, and ED3 in a plan view. The bank BNK may include openings surrounding the first to third light emitting elements ED1, ED2, and ED3 and overlap the light blocking member BM of the color filter layer CFL in the thickness direction. The bank BNK may include first to third banks BNK1, BNK2, and BNK3.

The first bank BNK1 may be disposed on the first insulating layer IL1, the second bank BNK2 may be disposed on the first bank BNK1, and the third bank BNK3 may be disposed on the second bank BNK2. A side surface of the first bank BNK1 and a side surface of the second bank BNK2 may be recessed inward from a side surface of the third bank BNK3. The side surface of the third bank BNK3 may protrude from the side surface of the second bank BNK2 toward the first light emitting element ED1, and the third bank BNK3 may include a protruding tip. Accordingly, a lower portion of the tip of the third bank BNK3 may have an undercut structure. A thickness of the first bank BNK1 may be greater than a thickness of the second bank BNK2 or the third bank BNK3 in the thickness direction.

For example, in a dry etching process, the first and second banks BNK1 and BNK2 may be etched more than the third bank BNK3. Accordingly, lateral shapes of the first to third banks BNK1, BNK2, and BNK3 may be determined by a difference in etching rates between the first to third banks BNK1, BNK2, and BNK3. The first bank BNK1, the first layer AE1a of the first pixel electrode AE1, the first layer AE2a of the second pixel electrode AD2, and the first layer AE3a of the third pixel electrode AE3 may be disposed on a same layer and include a same material. The second bank BNK2, the second layer AE1b of the first pixel electrode AE1, the second layer AE2b of the second pixel electrode AE2, and the second layer AE3b of the third pixel electrode AE3 may be disposed on a same layer and include a same material.

At least one of the first to third banks BNK1, BNK2, and BNK3 may include different metal materials. The first bank BNK1 may include a material having high electrical conductivity and high reflectivity. The first bank BNK1 may electrically connect first to third common electrodes CE1, CE2, and CE3 spaced apart from each other in the X-axis direction and/or the Y-axis direction. For example, the first bank BNK1 may include aluminum (Al) or the like, the second bank BNK2 may include titanium nitride (TiN) or the like, and the third bank BNK3 may include titanium (Ti) or the like, but the disclosure is not limited thereto.

The bank BNK may surround the first to third emitting elements ED1, ED2, and ED3 and the first to third pixel defining layer PDL1, PDL2, and PDL3 in the first to third emission areas EA1, EA2, and EA3 by a mask process, respectively, and the first to third common electrodes CE1, CE2, and CE3 may be formed on the first to third emitting elements ED1, ED2, and ED3 in the first to third emission areas EA1, EA2, and EA3, respectively. During a mask process is performed, a structure for mounting the mask may be required, and an excessively wide area of the non-display area NDA may be required to control distribution of the mask process. Accordingly, in case that the mask process is minimized, a structure for mounting a mask may be omitted, and an area of the non-display area NDA for distribution control may be minimized.

The electrode pattern CEP and the first to third common electrodes CE1, CE2, and CE3 may be formed in a same process and include a same metal material. A metal material may be deposited on a surface (e.g., an entire surface) of the display device 10, and the first to third common electrodes CE1, CE2, and CE3 and the electrode pattern CEP may be cut and separated from each other by a tip formed on an inner wall of the bank BNK. The electrode pattern CEP may be disposed on the third bank BNK3 in areas other than the first to third emission areas EA1, EA2, and EA3. The electrode pattern CEP may cover (or disposed on) top and side surfaces of the third bank BNK3.

The first to third light emitting elements ED1, ED2, and ED3 may be formed by a mask process and a deposition process. Since at least one of the first to third banks BNK1, BNK2, and BNK3 includes different metal materials, an inner wall of the bank BNK may have a tip structure, and the display device 10 may include different layers individually formed in the first to third emission areas EA1, EA2, and EA3 by a deposition process. For example, the first common electrode CE1 and the electrode pattern CEP may be deposited using a same organic material in (or by) a deposition process, and be cut and separated from each other by a tip formed on the inner wall of the bank BNK. The first common electrode CE1 may be disposed in the first emission area EA1, and the electrode pattern CEP may be disposed on the bank BNK in an area disposed between the first to third emission areas EA1, EA2, and EA3.

In the display device 10, the number of masks used in a mask process may be reduced by forming the first and second banks BNK1 and BNK2 and the first to third pixel electrodes AE1, AE2, and AE3 in a same process. The display device 10 may include first to third pixel defining layers PDL1, PDL2, and PDL3 defining the first to third emission areas EA1, EA2, and EA3, respectively, and the first to third light emitting layers EL1, EL2, and EL3 may be uniformly deposited. Accordingly, the display device 10 may reduce manufacturing cost by omitting unnecessary processes by separating the first to third light emitting elements ED1, ED2, and ED3 from each other by a deposition process, and an area of the non-display area NDA may be minimized.

In FIG. 5, the first layer AE1a and the second layer AE1b of the first pixel electrode AE1 and the first and second banks BNK1 and BNK2 may be disposed on a same layer. Heights of the first light emitting layer EL1 and the first common electrode CE1 may be similar to heights of the third bank BNK3 and the electrode pattern CEP with respect to the substrate SUB. For example, in case that the height of the first light emitting element ED1 is significantly lower than the height of the bank BNK, the light emitted from the first light emitting element ED1 may be blocked by the bank BNK and the light emitting efficiency of the first light emitting element ED1 may be deteriorated, making it difficult to implement a high-resolution ultra-fine process. In case that the height of the first light emitting element ED1 is similar to the height of the bank BNK, light emitted from the first light emitting element ED1 may not be blocked by the bank BNK. Accordingly, the display device 10 may include the first to third light emitting elements ED1, ED2, and ED3 having a height similar to a height of the bank BNK, thereby improving light emitting efficiency and readily implementing a high-resolution ultra-fine process.

The encapsulation layer TFEL may be disposed on the first to third common electrodes CE1, CE2, and CE3 and the electrode pattern CEP. The encapsulation layer TFEL may include first to third encapsulation layers TFE1, TFE2, and TFE3.

The first encapsulation layer TFE1 may be disposed on the first to third common electrodes CE1, CE2, and CE3 and the electrode pattern CEP. The first encapsulation layer TFE1 may cover (or be disposed on) side surfaces of the first and second banks BNK1 and BNK2 recessed inward from the side surfaces of the third bank BNK3. The first encapsulation layer TFE1 may include an inorganic material and prevent oxygen or moisture from permeating into the first to third light emitting elements ED1, ED2, and ED3. The first encapsulation layer TFE1 may be an inorganic encapsulation layer. For example, the first encapsulation layer TFE1 may include at least one of a silicon nitride, a silicon oxynitride, a silicon oxide, a titanium oxide, an aluminum oxide, and an amorphous silicon, but the disclosure is not limited thereto.

The second encapsulation layer TFE2 may be disposed on the first encapsulation layer TFE1 and planarize an upper end of the light emitting element layer EML. The second encapsulation layer TFE2 may include an organic material and protect the light emitting element layer EML from foreign substances such as dust or the like. For example, the second encapsulation layer TFE2 may include an organic film including an acrylic resin, an epoxy resin, a phenolic resin, a polyamide resin, a polyimide resin, the like, or a combination thereof. The second encapsulation layer TFE2 may be formed by curing a monomer, applying a polymer, or the like.

The third encapsulation layer TFE3 may be disposed on the second encapsulation layer TFE2. The third encapsulation layer TFE3 may include an inorganic material and prevent oxygen or moisture from permeating into the light emitting element layer EML. For example, the third encapsulation layer TFE3 may include at least one of a silicon nitride, a silicon oxynitride, a silicon oxide, a titanium oxide, an aluminum oxide, and an amorphous silicon, but the disclosure is not limited thereto.

The touch sensing part TSU may be disposed on the encapsulation layer TFEL. The touch sensing part TSU may include a third buffer layer BF3, a bridge electrode BRG, a second insulating layer IL2, touch electrodes TE, and a third insulating layer IL3.

The third buffer layer BF3 may be disposed on the encapsulation layer TFEL. The third buffer layer BF3 may have insulating, optical, and the like functions. The third buffer layer BF3 may include at least one inorganic layer. In another embodiment, the third buffer layer BF3 may be omitted.

The bridge electrode BRG may be disposed on the third buffer layer BF3. The bridge electrode BRG and the touch electrode TE may be disposed at different layers. The bridge electrode BRG may electrically connect adjacent touch electrodes TE to each other.

The second insulating layer IL2 may be disposed on the bridge electrode BRG and the third buffer layer BF3. The second insulating layer IL2 may have insulating, optical, and the like functions. For example, the second insulating layer IL2 may include at least one of a silicon nitride, a silicon oxynitride, a silicon oxide, a titanium oxide, an aluminum oxide, and an amorphous silicon, but the disclosure is not limited thereto.

The touch electrodes TE may be disposed on the second insulating layer IL2. The touch electrode TE may include a driving electrode and a sensing electrode, and sense a change in mutual capacitance between the driving electrode and the sensing electrode. The touch electrode TE may be not disposed in the first to third emission areas EA1, EA2, and EA3. The touch electrode TE may be formed as a single layer including molybdenum (Mo), titanium (Ti), copper (Cu), aluminum (Al), indium tin oxide (ITO), the like, or a combination thereof or be formed as a stacked structure (Ti/Al/Ti) of aluminum and titanium, a stacked structure (ITO/Al/ITO) of aluminum and ITO, an APC alloy, a stacked structure (ITO/APC/ITO) of an APC alloy and ITO, the like, or a combination thereof.

The third insulating layer IL3 may be disposed on the touch electrodes TE and the second insulating layer IL2. The third insulating layer IL3 may have insulating, optical, and the like functions. For example, the third insulating layer IL3 may include at least one of a silicon nitride, a silicon oxynitride, a silicon oxide, a titanium oxide, an aluminum oxide, and an amorphous silicon, but the disclosure is not limited thereto.

The color filter layer CFL may be disposed on the touch sensing part TSU. The color filter layer CFL may include a light blocking member BM, multiple color filters CF, and a planarization layer OC.

The light blocking member BM may be disposed on the third insulating layer IL3 and surround first to third color filters CF1, CF2, and CF3 in first to third optical areas OPT1, OPT2, and OPT3, respectively. The light blocking member BM may overlap the touch electrodes TE in the thickness direction. The light blocking member BM may include a light absorbing material and prevent light reflection. For example, the light blocking member BM may include an inorganic black pigment, an organic black pigment, an organic blue pigment, the like, or a combination thereof. The inorganic black pigment may be a metal oxide such as carbon black, titanium black, or the like, the organic black pigment may include at least one of lactam black, perylene black, and aniline black, and the organic blue pigment may be C.I. Pigment Blue or the like, but the disclosure is not limited thereto. The light blocking member BM may prevent color mixing due to permeation of visible light between the first to third emission areas EA1, EA2, and EA3 and improve a color gamut of the display device 10.

The color filters CF may include the first to third color filters CF1, CF2, and CF3. Each of the first to third color filters CF1, CF2, and CF3 may be disposed on the third insulating layer IL3 and correspond to each of the first to third emission areas EA1, EA2, and EA3.

The first color filter CF1 may be disposed in the first emission area EA1 on the third insulating layer IL3. The first color filter CF1 may be surrounded by the light blocking member BM in a plan view. An edge of the first color filter CF1 may cover (or be disposed on) a portion of an upper surface of the light blocking member BM, but the disclosure is not limited thereto. The first color filter CF1 may selectively transmit a light of the first color (e.g., the red light) through the first color filter CF1 and block or absorb a light of the second color (e.g., the green light) and a light of the third color (e.g., the blue light). For example, the first color filter CF1 may be a red color filter and include a red colorant or the like.

The second color filter CF2 may be disposed in the second emission area EA2 on the third insulating layer IL3. The second color filter CF2 may be surrounded by the light blocking member BM in a plan view. An edge of the second color filter CF2 may cover (or be disposed on) a portion of the upper surface of the light blocking member BM, but the disclosure is not limited thereto. The second color filter CF2 may selectively transmit the light of the second color (e.g., the green light) through the second color filter CF2 and block or absorb the light of the first color (e.g., the red light) and the light of the third color (e.g., the blue light). For example, the second color filter CF2 may be a green color filter and include a green colorant or the like.

The third color filter CF3 may be disposed in the third emission area EA3 on the third insulating layer IL3. The third color filter CF3 may be surrounded by the light blocking member BM in a plan view. An edge of the third color filter CF3 may cover (or a be disposed on) a portion of the upper surface of the light blocking member BM, but the disclosure is not limited thereto. The third color filter CF3 may selectively transmit the light of the third color (e.g., the blue light) through the third color filter CF3 and block or absorb the light of the first color (e.g., the red light) and the light of the second color (e.g., the green light). For example, the third color filter CF3 may be a blue color filter and include a blue colorant or the like.

The first to third color filters CF1, CF2, and CF3 may absorb a portion of light introduced from an outside of the display device 10 to reduce reflected light due to external light. Accordingly, the first to third color filters CF1, CF2, and CF3 may prevent distortion of colors due to external light reflection.

The planarization layer OC may be disposed on the light blocking member BM and the first to third color filters CF1, CF2, and CF3. The planarization layer OC may planarize an upper end of the color filter layer CFL. For example, the planarization layer OC may include an organic insulating material.

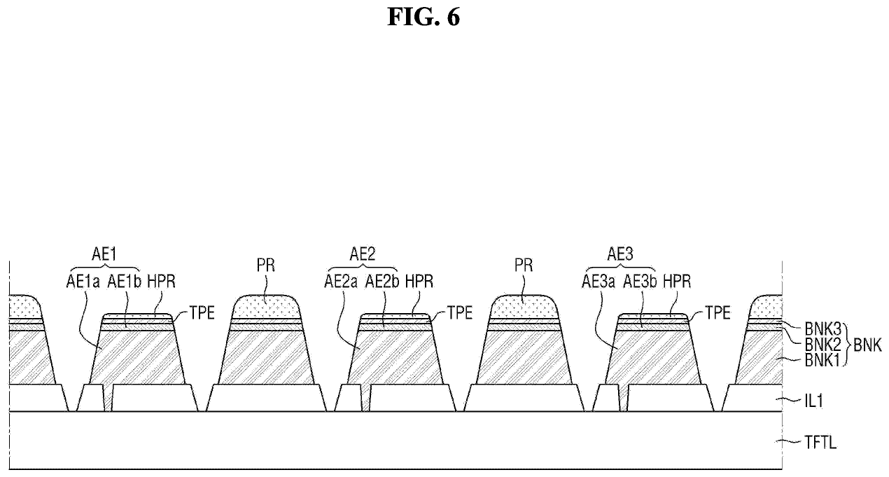

FIGS. 6 to 12 are schematic cross-sectional views illustrating a manufacturing process of a display device 10 of FIG. 4.

In FIG. 6, the first insulating layer IL1 may be disposed on the transistor layer TFTL. The first insulating layer IL1 may expose a portion of the transistor layer TFTL. The first insulating layer IL1 may include an inorganic insulating material. The first insulating layer IL1 may include at least one of a silicon nitride, a silicon oxynitride, a silicon oxide, a titanium oxide, an aluminum oxide, and an amorphous silicon, but the disclosure is not limited thereto.

The first layer AE1a of the first pixel electrode AE1 and a first bank BNK1 may be formed in a same process and include a same metal material. The second layer AE1b of the first pixel electrode AE1 and a second bank BNK2 may be formed in a same process and include a same metal material. A temporary pixel electrode TPE and the third bank BNK3 may be formed in a same process and include a same metal material. A thickness of the first layer AE1a of the first pixel electrode AE1 may be greater than a thickness of the second layer AE1b in the thickness direction. The first layer AE1a of the first pixel electrode AE1 may include a material having high electrical conductivity and high reflectivity. The second layer AE1b of the first pixel electrode AE1 may be an anode electrode for injecting holes. For example, the first layer AE1a of the first pixel electrode AE1 and the first bank BNK1 may include aluminum (Al) or the like, the second layer AE1b of the first pixel electrode AE1 and the second bank BNK2 may include titanium nitride (TiN) or the like, and the temporary pixel electrode TPE and the third bank BNK3 may include titanium (Ti) or the like, but the disclosure is not limited thereto.

The first to third pixel electrodes AE1, AE2, and AE3 may be spaced apart from each other in the X-axis direction and/or the Y-axis direction on a portion of the first insulating layer IL1. The first to third banks BNK1, BNK2, and BNK3 may be disposed on another portion of the first insulating layer IL1 and surround the first to third pixel electrodes AE1, AE2, and AE3 in a plan view. The first insulating layer IL1 may support the first to third pixel electrodes AE1, AE2, and AE3 and the bank BNK. A height of the first insulating layer IL1 may determine heights of the first to third light emitting elements ED1, ED2, and ED3 and the bank BNK. The first insulating layer IL1 supporting the first pixel electrode AE1, the first insulating layer IL1 supporting the second pixel electrode AE2, the first insulating layer IL1 supporting the third pixel electrode AE3, and the first insulating layer IL1 supporting the bank BNK may be spaced apart from each other in the X-axis direction and/or the Y-axis direction.

A photoresist PR may be disposed on the third bank BNK3, and a halftone photoresist HPR may be disposed on the temporary pixel electrode TPE. A thickness of the photoresist PR may be greater than a thickness of the halftone photoresist HPR in the thickness direction.

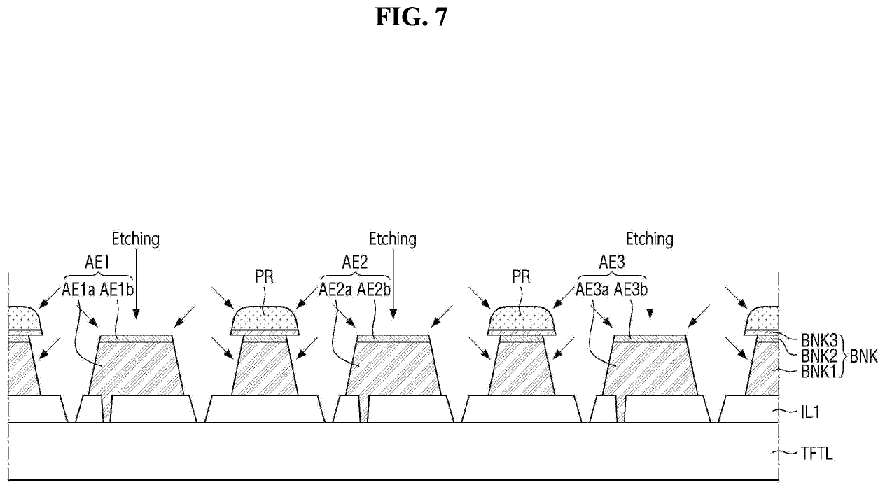

In FIG. 7, the first and second banks BNK1 and BNK2 and the temporary pixel electrode TPE may be etched by performing at least one of a dry etching process, a wet etching process, and the like. For example, the first and second banks BNK1 and BNK2 and the temporary pixel electrode TPE may be etched by an etching process such as an isotropic dry etching process or the like, but the disclosure is not limited thereto. The upper surface of the third bank BNK3 may be protected by the photoresist PR, but the side surfaces of the first and second banks BNK1 and BNK2 may not be protected by the photoresist PR. Accordingly, after the etching process is completed, the third bank BNK3 may remain, and the side surfaces of the first and second banks BNK1 and BNK2 may be recessed inward from the side surface of the third bank BNK3. A side surface of the third bank BNK3 may include a tip protruding from the side surface of the second bank BNK2. Accordingly, a lower portion of the tip of the third bank BNK3 may have an undercut structure.

The halftone photoresist HPR may be removed in an etching process such as an isotropic dry etching process or the like. An upper surface of the temporary pixel electrode TPE may not be protected by the halftone photoresist HPR. Accordingly, after the etching process is completed, the temporary pixel electrode TPE may be removed, and the second layers AE1b, AE2b, and AE3b of the first to third pixel electrodes AE1, AE2, and AE3 may be exposed.

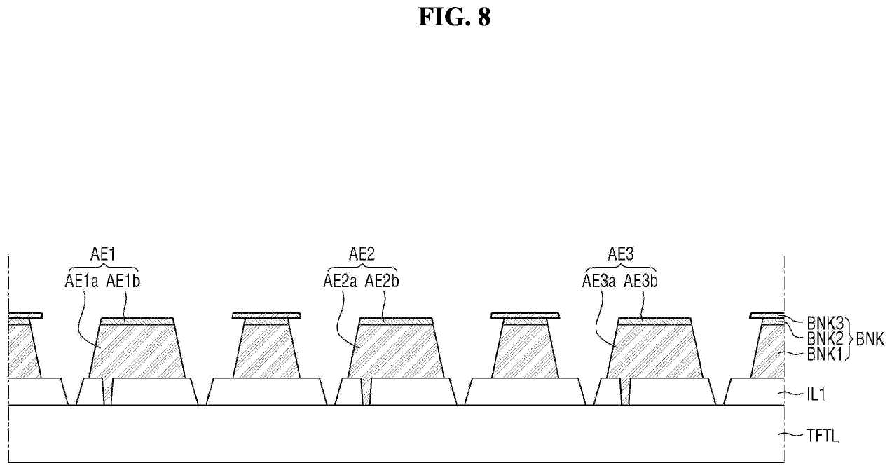

In FIG. 8, the photoresist PR may be removed by a strip process after etching of the first and second banks BNK1 and BNK2 is completed.

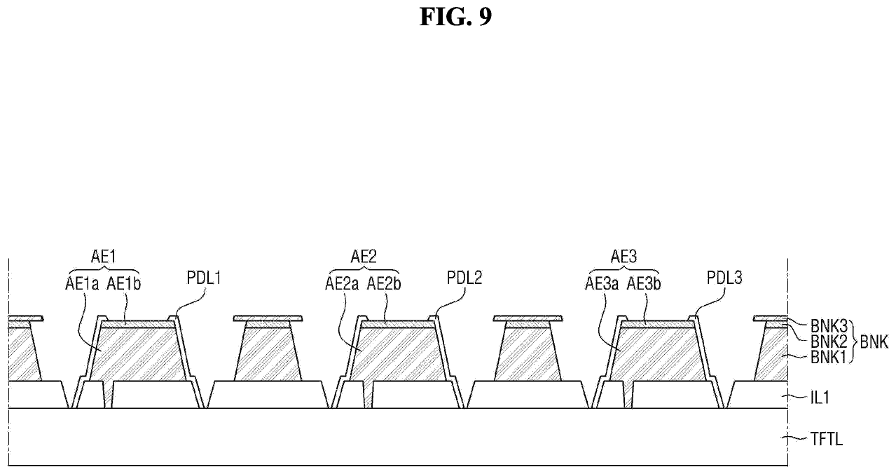

In FIG. 9, the first pixel defining layer PDL1 may define the first emission area EA1. The first pixel defining layer PDL1 may cover (or be disposed on) a side surface of the first insulating layer ILL disposed in the first emission area EA1, a side surface of the first pixel electrode AE1, and an edge of a top surface of the second layer AE1b of the first pixel electrode AE1. The first pixel defining layer PDL1 may expose a portion of the top surface of the second layer AE1b of the first pixel electrode AE1. The first pixel defining layer PDL1 may insulate the first pixel electrode AE1 from the first common electrode CE1.

The second pixel defining layer PDL2 may define the second emission area EA2. The second pixel defining layer PDL2 may cover (or be disposed on) a side surface of the first insulating layer IL1 disposed in the second emission area EA2, a side surface of the second pixel electrode AE2, and an edge of a top surface of the second layer AE2b of the second pixel electrode AE2. The second pixel defining layer PDL2 may expose a portion of the top surface of the second layer AE2b of the second pixel electrode AE2.

The third pixel defining layer PDL3 may define the third emission area EA3. The third pixel defining layer PDL3 may cover (or be disposed on) a side surface of the first insulating layer IL1 disposed in the third emission area EA3, a side surface of the third pixel electrode AE3, and an edge of a top surface of the second layer AE3b of the third pixel electrode AE3. The third pixel defining layer PDL3 may expose a portion of the top surface of the second layer AE3b of the third pixel electrode AE3.

The first to third pixel defining layers PDL1, PDL2, and PDL3 may include an inorganic insulating material. The first to third pixel defining layers PDL1, PDL2, and PDL3 may include at least one of a silicon nitride, a silicon oxynitride, a silicon oxide, a titanium oxide, an aluminum oxide, and an amorphous silicon, but the disclosure is not limited.

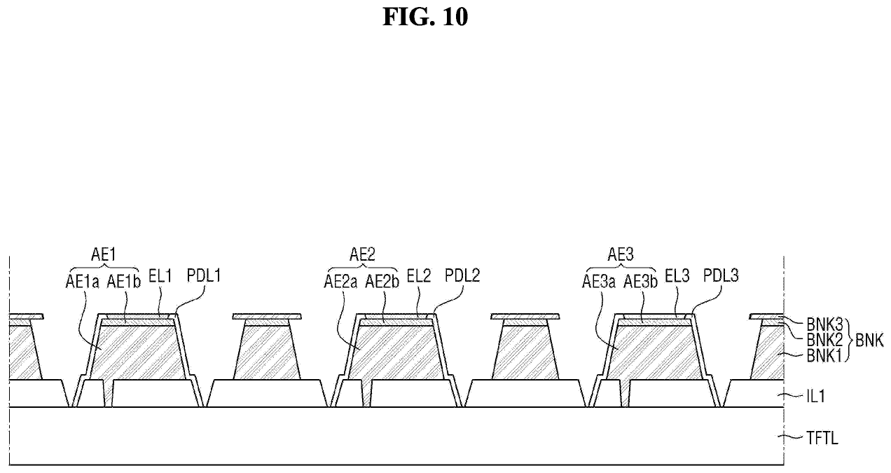

In FIG. 10, the first light emitting layer EL1 may be disposed (e.g., directly disposed) on the second layer AE1b of the first pixel electrode AE1 in the first emission area EA1. The first light emitting layer EL1 may fill a space surrounded by the first pixel defining layer PDL1.

The second light emitting layer EL2 may be disposed (e.g., directly disposed) on the second layer AE2b of the second pixel electrode AE2 in the second emission area EA2. The second light emitting layer EL2 may fill a space surrounded by the second pixel defining layer PDL2.

The third light emitting layer EL3 may be disposed (e.g., directly disposed) on the second layer AE3b of the third pixel electrode AE3 in the third emission area EA3. The third light emitting layer EL3 may fill a space surrounded by the third pixel defining layer PDL3.

The first to third light emitting layers EL1, EL2, and EL3 may be organic light emitting layers including organic materials. The first to third light emitting layers EL1, EL2, and EL3 may be uniformly deposited in the first to third emission areas EA1, EA2, and EA3 provided by the first to third pixel defining layers PDL1, PDL2, and PDL3. The first to third light emitting layers EL1, EL2, and EL3 may be uniformly deposited on an area surrounded by the first to third pixel defining layers PDL1, PDL2, and PLD3, respectively in the first to third emission areas EA1, EA2, and EA3, respectively.

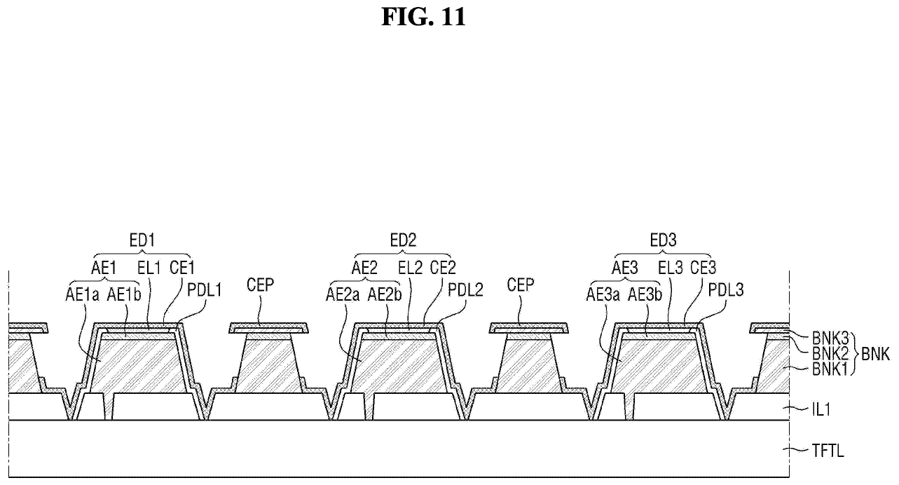

In FIG. 11, the first common electrode CE1 may be disposed on the first light emitting layer EL1. The first common electrode CE1 may cover (or be disposed on) the first pixel defining layer PDL1 and the first insulating layer IL1 and extend to a side surface of the first bank BNK1.

The second common electrode CE2 may be disposed on the second light emitting layer EL2. The second common electrode CE2 may cover (or be disposed on) the second pixel defining layer PDL2 and the first insulating layer IL1 and extend to a side surface of the first bank BNK1.

The third common electrode CE3 may be disposed on the third light emitting layer EL3. The third common electrode CE3 may cover (or be disposed on) the third pixel defining layer PDL3 and the first insulating layer IL1 and extend to the side of the first bank BNK1.

The first to third common electrodes CE1, CE2, and CE3 may contact side surfaces of the first bank BNK1 and be electrically connected to each other. For example, the first to third common electrodes CE1, CE2, and CE3 may receive a common voltage or a low potential voltage. The first to third common electrodes CE1, CE2, and CE3 may include a transparent conductive material and transmit light generated in the first to third light emitting layers EL1, EL2, and EL3.

The electrode pattern CEP and the first to third common electrodes CE1, CE2, and CE3 may be formed in a same process and include a same metal material. A metal material may be deposited on a surface (e.g., an entire surface) of the display device 10, and the first to third common electrodes CE1, CE2, and CE3 and the electrode pattern CEP may be cut and separated from each other by a tip formed on an inner wall of the bank BNK. The electrode pattern CEP may be disposed on the third bank BNK3 in areas other than the first to third emission areas EA1, EA2, and EA3. The electrode pattern CEP may cover (or be disposed on) top and side surfaces of the third bank BNK3.

The first to third light emitting elements ED1, ED2, and ED3 may be formed by a mask process and a deposition process. Since at least one of the first to third banks BNK1, BNK2, and BNK3 includes a different metal material, an inner wall of the bank BNK may have a tip structure, and the display device 10 may include different layers individually formed in the first to third emission areas EA1, EA2, and EA3 by a deposition process. For example, the first common electrode CE1 and the electrode pattern CEP may be deposited using a same organic material in (or by) a deposition process, and be cut and separated from each other by a tip formed on the inner wall of the bank BNK. The first common electrode CE1 may be disposed in the first emission area EA1, and the electrode pattern CEP may be disposed on the bank BNK in an area disposed between the first to third emission areas EA1, EA2, and EA3.

In the display device 10, the number of masks used in a mask process may be reduced by forming the first and second banks BNK1 and BNK2 and the first to third pixel electrodes AE1. AE2, and AE3 in a same process. Accordingly, the display device 10 may reduce manufacturing cost by omitting unnecessary processes by separating the first to third light emitting elements ED1, ED2, and ED3 from each other by a deposition process, and an area of the non-display area NDA may be minimized.

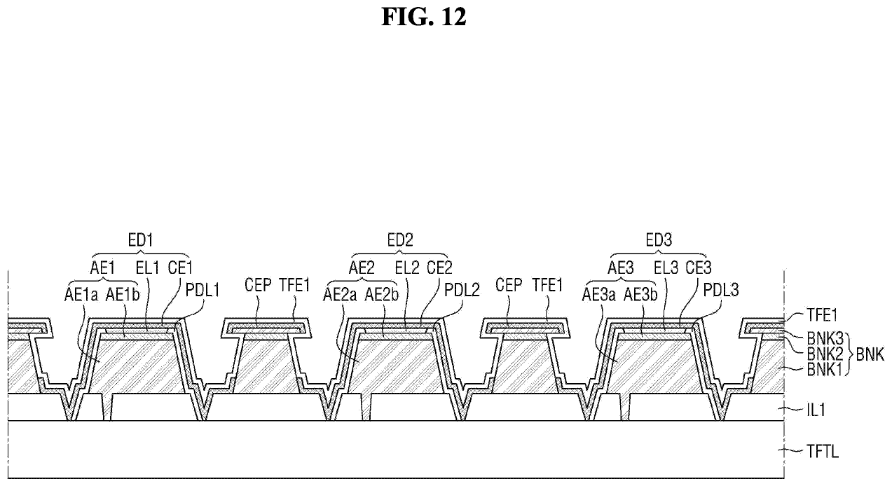

In FIG. 12, the first encapsulation layer TFE1 may be disposed on the first to third common electrodes CE1, CE2, and CE3 and the electrode pattern CEP. The first encapsulation layer TFE1 may cover (or be disposed on) side surfaces of the first and second banks BNK1 and BNK2 recessed inward from the side surfaces of the third bank BNK3. The first encapsulation layer TFE1 may include an inorganic material and prevent oxygen or moisture from permeating into the first to third light emitting elements ED1, ED2, and ED3. The first encapsulation layer TFE1 may be an inorganic encapsulation layer. For example, the first encapsulation layer TFE1 may include at least one of a silicon nitride, a silicon oxynitride, a silicon oxide, a titanium oxide, an aluminum oxide, and an amorphous silicon, but the disclosure is not limited thereto.

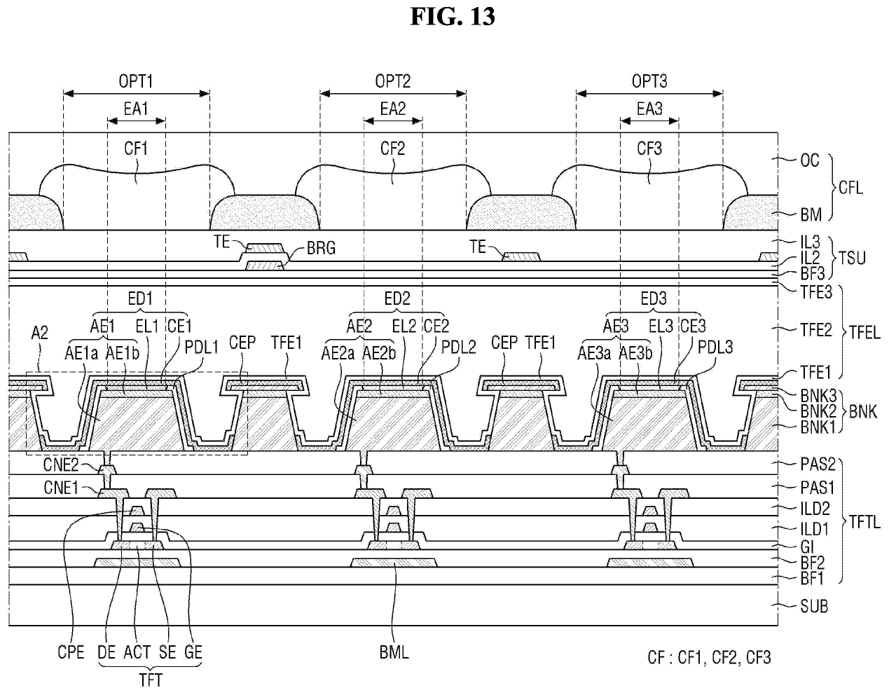

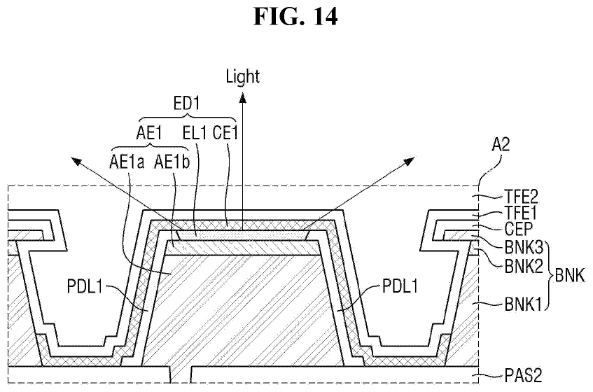

FIG. 13 is a schematic cross-sectional view illustrating a portion of a display device 10 according to another embodiment, and FIG. 14 is a schematic enlarged view of area A2 of FIG. 13. The display device 10 of FIGS. 13 and 14 and the display device 10 of FIGS. 4 and 5 may differ from each other in the configurations of the first to third pixel electrodes AE1, AE2, and AE3 by omitting the configuration of the first insulating layer IL1. A description of a same configuration as the above-described configuration will be briefly given or omitted.

Referring to FIGS. 2, 13, and 14, the display panel 100 may include a display part DU, a touch sensing part TSU, and a color filter layer CFL. The display part DU may include the substrate SUB, the transistor layer TFTL, the light emitting element layer EML, and the encapsulation layer TFEL.

The light emitting element layer EML may be disposed on the transistor layer TFTL. The light emitting element layer EML may include first to third light emitting elements ED1, ED2, and ED3, first to third pixel defining layers PDL1, PDL2, and PDL3, banks BNK, and electrode patterns CEP.

The first light emitting element ED1 may be disposed in the first emission area EA1 on the second passivation layer PAS2. The first light emitting element ED1 may include a first pixel electrode AE1, a first light emitting layer EL1, and a first common electrode CE1.

The first pixel electrode AE1 may be disposed on the second passivation layer PAS2. The first pixel electrode AE1 may be inserted into a contact hole provided in the second passivation layer PAS2 and contact the second connection electrode CNE2. The first pixel electrode AE1 may be electrically connected to the drain electrode DE of the transistor TFT through the first and second connection electrodes CNE1 and CNE2.

The first pixel electrode AE1 may include a first layer AE1a and a second layer AE1b. The first layer AE1a of the first pixel electrode AE1 may be disposed on the second passivation layer PAS2, and the second layer AE1b of the first pixel electrode AE1 may be disposed on the first layer AE1a. The first layer AE1a of the first pixel electrode AE1 and the first bank BNK1 may be formed in a same process and include a same metal material. The second layer AE1b of the first pixel electrode AE1 and the second bank BNK2 may be formed in a same process and include a same metal material. A thickness of the first layer AE1a of the first pixel electrode AE1 may be greater than a thickness of the second layer AE1b in the thickness direction.

The first layer AE1a and the second layer AE1b of the first pixel electrode AE1 may include different metal materials from each other. The first layer AE1a of the first pixel electrode AE1 may include a material having high electrical conductivity and high reflectivity. The second layer AE1b of the first pixel electrode AE1 may be an anode electrode for injecting holes. For example, the first layer AE1a of the first pixel electrode AE1 may include aluminum (Al) or the like, and the second layer AE1b of the first pixel electrode AE1 may include titanium nitride (TiN) or the like, but the disclosure is not limited thereto.

The first pixel defining layer PDL1 may define the first emission area EA1. The first pixel defining layer PDL1 may cover (or be disposed on) a side surface of the first pixel electrode AE1 and an edge of a top surface of the second layer AE1b of the first pixel electrode AE1. The first pixel defining layer PDL1 may expose a portion of the top surface of the second layer AE1b of the first pixel electrode AE1. The first pixel defining layer PDL1 may insulate the first pixel electrode AE1 from the first common electrode CE1. The first pixel defining layer PDL1 may include an inorganic insulating material. The first pixel defining layer PDL1 may include at least one of a silicon nitride, a silicon oxynitride, a silicon oxide, a titanium oxide, an aluminum oxide, and an amorphous silicon, but the disclosure is not limited thereto.

The first light emitting layer EL1 may be an organic light emitting layer including an organic material. The first light emitting layer EL1 may be disposed (e.g., directly disposed) on the second layer AE1b of the first pixel electrode AE1 in the first emission area EA1. The first light emitting layer EL1 may fill a space surrounded by the first pixel defining layer PDL1.

The first common electrode CE1 may be disposed on the first light emitting layer EL1. The first common electrode CE1 may cover (or be disposed on) the first pixel defining layer PDL1 and the second passivation layer PAS2 and extend to a side surface of the first bank BNK1. The first common electrode CE1 may be electrically connected to the second and third common electrodes CE2 and CE3 through the first bank BNK1 by contacting the side surface of the first bank BNK1. For example, the first common electrode CE1 may receive a common voltage or a low potential voltage. The first common electrode CE1 may include a transparent conductive material and transmit light generated in the first light emitting layer EL1.

The first pixel electrode AE1 may receive a voltage corresponding to the data voltage from the transistor TFT and the first common electrode CE1 may receive a common voltage or a cathode voltage. In case that a potential difference is formed between the first pixel electrode AE1 and the first common electrode CE1, holes may move to the first light emitting layer EL1 through the hole transporting layer, and electrons may move to the first light emitting layer EL1 through the electron transporting layer, and the first light emitting layer EL1 may emit light.

Since the second light emitting element ED2, the third light emitting element ED3, and the first light emitting element ED1 may be formed in a same manner, the descriptions of the second and third light emitting elements ED2 and ED3 will be omitted.

The bank BNK may be disposed on the second passivation layer PAS2 and surround the first to third light emitting elements ED1, ED2, and ED3 in a plan view. The bank BNK may include openings surrounding the first to third light emitting elements ED1, ED2, and ED3 and overlap the light blocking member BM of the color filter layer CFL in the thickness direction. The bank BNK may include first to third banks BNK1, BNK2, and BNK3.

The first bank BNK1 may be disposed on the second passivation layer PAS2, the second bank BNK2 may be disposed on the first bank BNK1, and the third bank BNK3 may be disposed on the second bank BNK2. A side surface of the first bank BNK1 and side surface of the second bank BNK2 may be recessed inward from a side surface of the third bank BNK3. The side surface of the third bank BNK3 may protrude from the side surface of the second bank BNK2 toward the first light emitting element ED1, and the third bank BNK3 may include a protruding tip. Accordingly, a lower portion of the tip of the third bank BNK3 may have an undercut structure. A thickness of the first bank BNK1 may be greater than a thickness of the second bank BNK2 or the third bank BNK3 in the thickness direction.

For example, in a dry etching process, the first and second banks BNK1 and BNK2 may be etched more than the third bank BNK3. Accordingly, the lateral shapes of the first to third banks BNK1, BNK2, and BNK3 may be determined by a difference in etching rates between the first to third banks BNK1, BNK2, and BNK3. The first bank BNK1, the first layer AE1a of the first pixel electrode AE1, the first layer AE2a of the second pixel electrode AE2, and the first layer AE3a of the third pixel electrode AE3 may be formed in a same process and include a same material. The second bank BNK2, the second layer AE1b of the first pixel electrode AE1, the second layer AE2b of the second pixel electrode AE2, and the second layer AE3b of the third pixel electrode AE3 may be formed in a same process and include a same material.

At least one of the first to third banks BNK1, BNK2, and BNK3 may include different metal materials from each other. The first bank BNK1 may include a material having high electrical conductivity and high reflectivity. The first bank BNK1 may electrically connect first to third common electrodes CE1, CE2, and CE3 spaced apart from each other in the X-axis direction and/or the Y-axis direction. For example, the first bank BNK1 may include aluminum (Al) or the like, the second bank BNK2 may include titanium nitride (TiN) or the like, and the third bank BNK3 may include titanium (Ti) or the like, but the disclosure is not limited thereto.

The bank BNK may surround the first to third emitting elements ED1, ED2, and ED3 and the first to third pixel defining layer PDL1, PDL2, and PLD3 in the first to third emission areas EA1, EA2, and EA3 by a mask process, respectively, and the first to third common electrodes CE1, CE2, and CE3 may be formed on the first to third emitting elements ED1, ED2, and ED3 in the first to third emission areas EA1, EA2, and EA3, respectively. In case that a mask process is performed, a structure for mounting the mask may be required, and an excessively wide area of the non-display area NDA may be required to control distribution of the mask process. Accordingly, in case that the mask process is minimized, a structure for mounting a mask may be omitted, and an area of the non-display area NDA for distribution control may be minimized.

In the display device 10, the number of masks used in a mask process may be reduced by forming the first and second banks BNK1 and BNK2 and the first to third pixel electrodes AE1, AE2, and AE3 in a same process. The display device 10 may include first to third pixel defining layers PDL1, PDL2, and PDL3 defining the first to third emission areas EA1, EA2, and EA3, so that the first to third light emitting layers EL1, EL2, and EL3 may be uniformly deposited. Accordingly, the display device 10 may reduce manufacturing cost by omitting unnecessary processes by separating the first to third light emitting elements ED1, ED2, and ED3 from each other by a deposition process, and an area of the non-display area NDA may be minimized.

In FIG. 14, the first layer AE1a and the second layer AE1b of the first pixel electrode AE1 and the first and second bank BNK1 and BNK2 may be disposed on a same layer. Heights of the first light emitting layer EL1 and the first common electrode CE1 may be similar to heights of the third bank BNK3 and the electrode pattern CEP with respect to the substrate SUB. For example, in case that the height of the first light emitting element ED1 is significantly less than the height of the bank BNK, the light emitted from the first light emitting element ED1 may be blocked by the bank BNK, the light emitting efficiency of the first light emitting element ED1 may be deteriorated, making it difficult to implement a high-resolution ultra-fine process. In case that the height of the first light emitting element ED1 is similar to the height of the bank BNK, light emitted from the first light emitting element ED1 may not be blocked by the bank BNK. Accordingly, the display device 10 may include the first to third light emitting elements ED1, ED2, and ED3 having a height similar to a height of the bank BNK, thereby improving light emitting efficiency and readily implementing a high-resolution ultra-fine process.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a transistor layer disposed on a substrate and comprising at least one transistor;
an insulating layer disposed on the transistor layer;
a first pixel electrode disposed on the insulating layer;
a first pixel defining layer covering a side surface of the first pixel electrode and a side surface of the insulating layer and defining a first emission area;
a first light emitting layer disposed in the first emission area on the first pixel electrode;
a first common electrode disposed on the first light emitting layer; and
a bank disposed on the insulating layer and surrounding the first pixel electrode,
wherein the first pixel electrode and the bank are disposed on a same layer and comprise a same material.

2. The display device of claim 1, wherein the bank comprises:
a first bank disposed on the insulating layer;
a second bank disposed on the first bank; and
a third bank disposed on the second bank.

3. The display device of claim 2, wherein a side surface of the first bank and a side surface of the second bank are recessed inward from a side surface of the third bank.

4. The display device of claim 2, wherein the third bank comprises a tip protruding from a side surface of the second bank.

5. The display device of claim 2, wherein the first common electrode covers the first pixel defining layer and the insulating layer and extends to a side surface of the first bank.

6. The display device of claim 2, wherein the first pixel electrode comprises:
a first layer disposed on the insulating layer; and
a second layer disposed on the first layer.

7. The display device of claim 6, wherein
the first layer of the first pixel electrode and the first bank are disposed on a same layer and comprise a same material, and
the second layer of the first pixel electrode and the second bank are disposed on a same layer and comprise a same material.

8. The display device of claim 2, further comprising:
a second pixel electrode disposed on the insulating layer;
a second pixel defining layer covering a side surface of the insulating layer and a side surface of the second pixel electrode and defining a second emission area;
a second light emitting layer disposed in the second emission area on the second pixel electrode; and
a second common electrode disposed on the second light emitting layer.

9. The display device of claim 8, wherein the second pixel electrode comprises:
a first layer, the first layer and the first bank disposed on a same layer and comprising a same material; and
a second layer, the second layer and the second bank disposed on a same layer and comprising a same material.

10. The display device of claim 8, wherein the first and second common electrodes are electrically connected through the first bank.

11. The display device of claim 2, further comprising:
an electrode pattern disposed on the third bank, the electrode pattern and the first common electrode comprising a same material.

12. The display device of claim 11, further comprising:
a first encapsulation layer disposed on the first common electrode and the electrode pattern, and covering side surfaces of the first and second banks.

13. A display device comprising:
a transistor layer disposed on a substrate and comprising at least one transistor;
a first pixel electrode disposed on the transistor layer;
a first pixel defining layer covering a side surface of the first pixel electrode and defining a first emission area;
a first light emitting layer disposed in the first emission area on the first pixel electrode;
a first common electrode disposed on the first light emitting layer; and
a bank disposed on the transistor layer and surrounding the first pixel electrode,
wherein the first pixel electrode and the bank are disposed on a same layer and comprise a same material.

14. The display device of claim 13, wherein the bank comprises:
a first bank disposed on the transistor layer;
a second bank disposed on the first bank; and
a third bank disposed on the second bank.

15. The display device of claim 14, wherein the first pixel electrode comprises:
a first layer, the first layer and the first bank disposed on a same layer and comprising a same material; and
a second layer, the second layer and the second bank disposed on a same layer and comprising a same material.

16. A method of manufacturing a display device, the method comprising:
forming an insulating layer on a substrate;
forming a first layer of a first pixel electrode and a first bank on the insulating layer;
forming a second layer of a first pixel electrode on the first layer of the first pixel electrode and forming a second bank on the first bank;
forming a temporary pixel electrode on the second layer of the first pixel electrode and forming a third bank on the second bank;
forming a halftone photoresist on the temporary pixel electrode and forming a photoresist that is thicker than the halftone photoresist on the third bank; and
removing the halftone photoresist and the temporary pixel electrode through an etching process and etching a side surface of the first bank and a side surface of the second bank to form a tip of the third bank.

17. The method of claim 16, further comprising:
removing the photoresist through a stripping process.

18. The method of claim 17, further comprising:
forming a first pixel defining layer covering a side surface of the insulating layer, a side surface of the first pixel electrode, and an edge of a top surface of the second layer of the first pixel electrode to define a first emission area.

19. The method of claim 18, further comprising:
forming a first light emitting layer in the first emission area on the second layer of the first pixel electrode.

20. The method of claim 19, further comprising:
forming a first common electrode on the first light emitting layer and forming an electrode pattern on the third bank,
wherein the forming of the first common electrode and the forming of the electrode pattern comprises depositing a metal material to cut and separate first common electrode and the electrode pattern by the tip of the third bank.
